(19) United States
(12) Patent Application Publication
(10) Pub. No.: US 2004/0113263 A1
(43) Pub. Date: Jun. 17, 2004

(54) Semiconductor package structure provided with heat sink fan

(76) Inventor: Wan-Hua Wu, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/320,448

(22) Filed: Dec. 17, 2002

(51) Int. Cl. H01L 23/10

(52) U.S. Cl. 257/706

(57) ABSTRACT

The present invention is to provide a semiconductor package structure provided with the heat sink fan. The present invention is to arrange at least a chip and a heat sink fan on a substrate. A trench is positioned surrounding around a surface of the external exposed portion of the heat sink fan so as to block the encapsulant, which is to cover the chip, in the trench to prevent the encapsulant to overflow the surface of the heat sink fan. In the present invention, the surrounding of the exposed surface of the heat sink fan can maintain the uniform appearance and retain the fixed heat-sinking area so as to assure the heat-sinking efficiency.

### BACKGROUND OF THE INVENTION

1. Field of the Invention

The present invention generally relates to an improvement of a semiconductor package structure, and more particularly relates to a ball grid array (BGA) semiconductor package structure provided with the heat sink fan.

2. Description of the Prior Art

Accordingly, with the improvement of the integrated circuit (IC) technology, the enhancement trend of the level and the function of the electronic product can be generalized as the function, the high speed, the high density, and the compact size. In order to achieve the previous trends, not only the improvement of the integrated circuit (IC) technology is been pushed, but also many novel package technology and material are developed.

Due to the lead of the semiconductor package device become more and more, the density of the device become higher and higher, and the speed require become faster and faster, the package device of the compact size, the high speed, and the high density become a trend. Furthermore, the power consumption of the package device become larger and larger so as to cause the heat-sinking problem of the package device becomes more and more important. In order to shorten the gateway for heat-sinking, and to enhance the heat-sinking efficiency and the effective heat-sinking area, in the prior technology, the substrate 10 of the ball grid array package device is positioned a heat sink fan 12, such as shown in the FIG. 1. The heat sink fan covers the chip 14 of the substrate 10 so as to enhance the heat-sinking efficiency. Last, the prior technology utilizes an encapsulant 16 to cover each device and only expose the external exposed portion of the heat sink fan 12.

However, in the general manufacturing process, in order to prevent the encapsulant completely covert the heat sink fan 12, it utilizes the upward surface of the heat sink fan 12 to joint to the surface of the molding hole of the transfer molding to prevent the encapsulant 16 overflowing the surface of the heat sink fan 12. However, the encapsulant 16 has the high mobility and it is difficult to control the mobility so as to easily cause the overflowing in the surrounding of the exposed circle surface of the heat sink fan 12, such as the dotted line shown in the FIG. 1. In the prior technology, it can maintain a uniform appearance at the surrounding of the exposed circle surface. However, because the encapsulant 16 overflows the surface of the heat sink fan 12, so the heat-sinking area of the heat sink fan 12 is lessening so as to affect the heat-sinking efficiency of the package device.

Hence, the main spirit of the invention is to provide a semiconductor package structure provided with the heat sink fan, and then some disadvantages of well-known technology are overcome.

### SUMMARY OF THE INVENTION

The primary object of the present invention is to provide a semiconductor package structure provided with the heat sink fan, wherein a trench is positioned at the external exposed surface of the heat sink fan. The present invention utilizes the trench to block the encapsulant therein so as to effectively prevent the encapsulant to overflow the surface of the heat sink fan.

Another object of the present invention is to provide a semiconductor package structure provided with the heat sink fan, wherein the surrounding of the exposed surface of the heat sink fan can maintain the uniform appearance and retain the fixed heat-sinking area so as to assure the heat-sinking efficiency.

In order to achieve previous objects, the present invention is to form a plurality of solder balls arranged under a substrate and at least a chip bearing on the substrate. The chip and the substrate are electrically connecting. There is a heat sink fan, which is upward and prominent to form an external exposed portion and a trench is positioned surrounding around a surface of the external exposed portion and the heat sink fan is arranged on the surface of the substrate to cover the chip. Then, an encapsulant is utilized to cover the chip and the heat sink fan. The trench is to block the encapsulant so as to expose the external exposed portion of the heat sink fan out of the encapsulant.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic representation of the cutaway view of the architecture of a ball grid array device provided with the heat sink fan, in accordance with the prior technology;

FIG. 2 is a schematic representation of the cutaway view of the architecture of a ball grid array device provided with the heat sink fan, in accordance with the present invention;

FIG. 3 is a schematic representation of the cutaway view of the architecture of the heat sink fan, in accordance with the present invention; and

FIG. 4 is a schematic representation of the vertical view of the architecture of the heat sink fan, in accordance with the present invention.

### DESCRIPTION OF THE PREFERRED EMBODIMENT

The present invention is to design a ring type trench on the external exposed surface of the heat sink fan of the semiconductor package structure. Hence, the encapsulant of the present invention can be stopped in the trench. The present invention can prevent the overflowing of the encapsulant to assure the external exposed area and to enhance the heat-sinking efficiency. In the following description, a ball grid array (BGA) semiconductor package structure provided with the wire bonding structure is utilized to illustrate the function of the present invention.

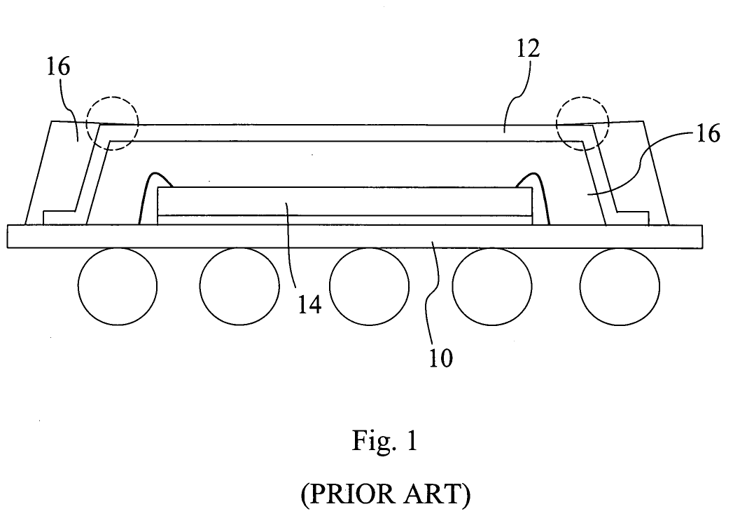

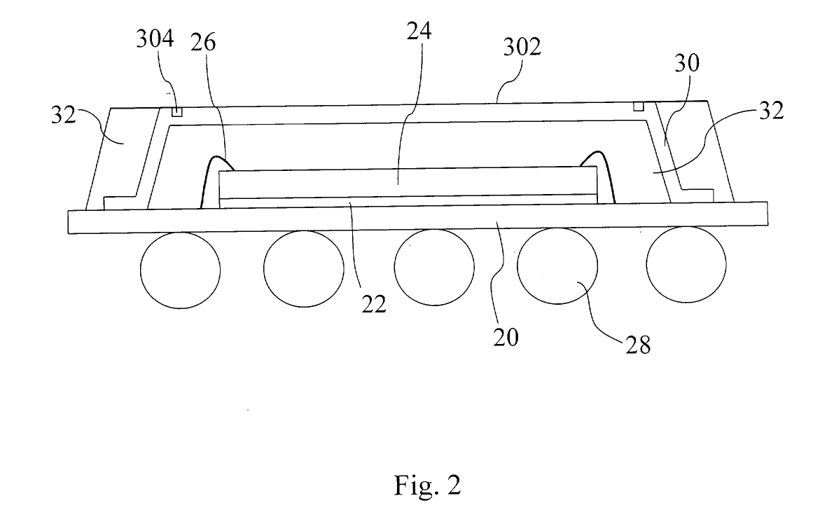

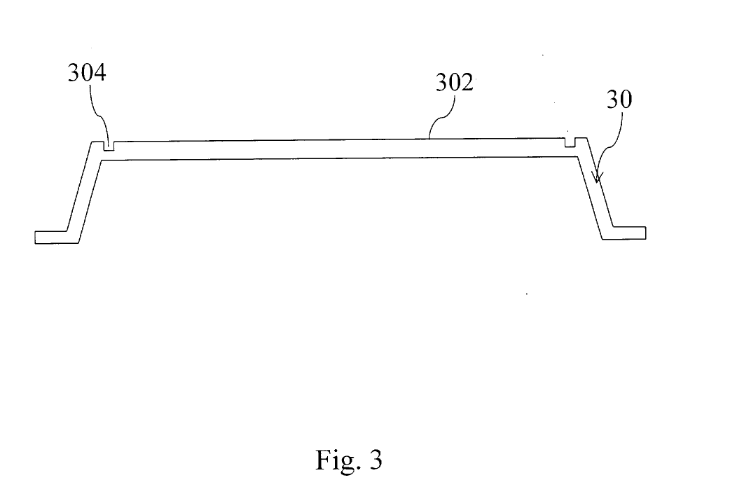

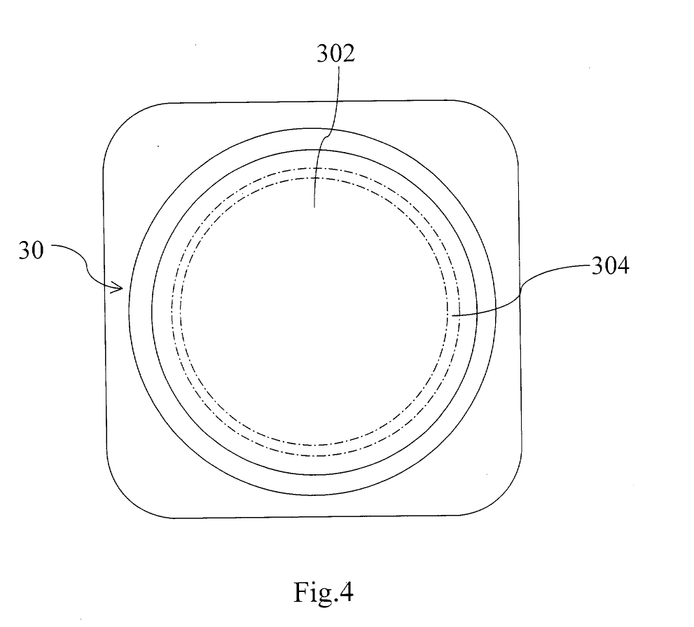

Referring to the FIG. 2, it is a schematic representation of the cutaway view of the architecture of a ball grid array device provided with the heat sink fan. Such as shown in the FIG. 1, in a semiconductor package structure, a substrate 20 is provided with a first surface and a second surface. At the first surface of the substrate 20, a semiconductor chip 24, which has the electron circuit therein, is attached thereon by using the adhesives 22. Then, a wire bonder is utilized to connect the leading wire 26 with the input/output connecting point of the chip 24 and the bonding point of the substrate 20. A plurality of solder balls is arranged on the second surface of the substrate 20 for using as the external connecting points to provide to bind to the main broad or other electronic equipments. Furthermore, a heat sink fan 30 is upward and prominent to form a circle surface external exposed portion 302. Simultaneously referring to the FIG. 3 and FIG. 4, the surrounding of the surface of the circle surface external exposed portion 302 is positioned a circle trench 304. The heat sink fan 30 and the external exposed portion 302 thereof and the trench are direct soling. The heat sink fan 30 is utilizing the adhesives to attach on the first surface of the substrate 20 to cover the chip 24. The external exposed portion 302 of the heat sink fan 30 is just at the top of the chip 24. The encapsulant 32 of the most outer layer is using the molding compound, which is usually using the epoxy resin, to mold to cover the chip 24 to merely expose the external exposed portion 302 of the heat sink fan 30 to provide the protection of the mechanism to prevent the chip damaging from the external force.

Wherein, in the transfer molding process, the encapsulant 32 of the most outer layer is to be blocked by the trench 304 surrounding the external exposed portion 302 of the heat sink fan 30 and to stop in the trench 304. The encapsulant 32 would not overflow into the circle surface external exposed portion 302 of the heat sink fan 30 so as to maintain the uniform circle appearance of the circle surface external exposed portion 302 of the heat sink fan 30 and to effectively prevent the encapsulant 32 overflowing the surface of the heat sink fan without effecting the heat-sinking area and the heat-sink effect.

Besides, the heat sink fan of the present invention not only can present an appearance shape of a circle surface, but also can present an appearance shape of a square surface.

Hence, the present invention utilizes a trench arranged at the external exposed surface of the heat sink fan so as to block the encapsulant in the trench to effectively prevent the encapsulant to overflow the surface of the heat sink fan. So, the surrounding of the exposed surface of the heat sink fan can maintain the uniform appearance and retain the fixed heat-sinking area without overflowing by the encapsulant so as to assure the heat-sinking efficiency in the semiconductor package structure.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A semiconductor package structure provided with a heat sink fan including:
a substrate having a first surface and a second surface;
at least a chip positioned on said first surface of said substrate and electrically connecting therewith;
a heat sink fan upward and prominent to form an external exposed portion, wherein a trench is positioned surrounding around a surface of said external exposed portion and said heat sink fan is arranged on said first surface of said substrate to cover said chip; and
an encapsulant to lay over said chip and a portion of said heat sink fan to block said encapsulant by said trench so as to expose said external exposed portion of said heat sink fan out of said encapsulant.

2. The semiconductor package structure provided with a heat sink fan according to claim 1, wherein a plurality of solder balls are arranged on said second surface of said substrate for using as external connecting points.

3. The semiconductor package structure provided with a heat sink fan according to claim 1, wherein said external exposed portion of said heat sink fan is presented a shape of a circle surface or a square surface.

4. The semiconductor package structure provided with a heat sink fan according to claim 1, wherein said heat sink fan is made of the metal material.

5. The semiconductor package structure provided with a heat sink fan according to claim 1, wherein said heat sink fan and said external exposed portion thereof and said trench are formed by direct soling.

6. A heat sink fan is applying for a semiconductor package structure, wherein said heat sink fan is upward and prominent to form an external exposed portion and a trench is positioned surrounding around a surface of said external exposed portion.

7. The heat sink fan applying for a semiconductor package structure according to claim 6, said external exposed portion of said heat sink fan is presented a shape of a circle surface or a square surface.

8. The heat sink fan applying for a semiconductor package structure according to claim 6, wherein said heat sink fan is made of the metal material.

9. The heat sink fan applying for a semiconductor package structure according to claim 6, said heat sink fan and said external exposed portion thereof and said trench are formed by direct soling.
